(19) United States
(12) Patent Application Publication
(10) Pub. No.: US 2014/0021591 A1
(43) Pub. Date: Jan. 23, 2014

(54) EMI SHIELDING SEMICONDUCTOR ELEMENT AND SEMICONDUCTOR STACK STRUCTURE

(71) Applicant: SILICONWARE PRECISION INDUSTRIES CO., LTD., Taichung (TW)

(72) Inventors: Tse-Shih Sung, Taichung (TW); Wen-Jung Chiang, Taichung (TW); Hsin-Hung Lee, Taichung (TW)

(73) Assignee: SILICONWARE PRECISION INDUSTRIES CO., LTD., Taichung (TW)

(21) Appl. No.: 13/728,112

(22) Filed: Dec. 27, 2012

(30) Foreign Application Priority Data
Jul. 19, 2012 (TW) 101125981

(51) Int. Cl. H01L 23/60

(52) U.S. Cl. CPC H01L 23/60
USPC 257/659

(57) ABSTRACT

A semiconductor element is provided, including: a substrate having a plurality of first conductive through holes and second conductive through holes formed therein; a redistribution layer formed on the substrate and having a plurality of conductive pads electrically connected to the first conductive through holes; and a metal layer formed on the redistribution layer and electrically connected to the second conductive through holes. The metal layer further has a plurality of openings for the conductive pads of the redistribution layer to be exposed from the openings without electrically connecting the first metal layer. As such, the metal layer and the second conductive through holes form a shielding structure that can prevent passage of electromagnetic waves into or out of the redistribution layer or side surfaces of the semiconductor element, thereby effectively shield electromagnetic interference.

### BACKGROUND OF THE INVENTION

1. Field of the Invention

The present invention relates to semiconductor elements, and, more particularly, to an EMI (Electromagnetic Interference) shielding semiconductor element.

2. Description of Related Art

To meet the demands for multi-functional and mini-sized electronic products, more and more chips and functions need to be integrated in a limited of a chip carrier area.

Accordingly, 3D-IC chip stack technologies have been developed.

In a 3D-IC chip structure, a plurality of chips are vertically stacked on one another for integration. According to current 3D-IC chip technologies, after a plurality of chips having different functions were fabricated through various processes, the chips are vertically stacked on one another by using through silicon via (TSV) technologies to shorten signal transmission paths, reduce the resistance and power consumption, and meet the miniaturization requirement of electronic products. However, electromagnetic interference can easily occur between the chips.

FIG. 1 shows a conventional 3D-IC chip stack semiconductor package 1. Two chips 11a, 11b having TSVs 110a, 110b are stacked on a carrier 10, and the two chips 11a, 11b are bonded together through an insulating layer 14. Further, an underfill 16 is filled between the lower chip 11b and the carrier 10, and an encapsulant 13 is formed to encapsulate the chips 11a, 11b.

Conventionally, each of the chips 11a, 11b has a redistribution layer (not shown) formed at one side thereof for conductive elements 111, 15 to be mounted thereon, thus allowing a semiconductor element to be stacked on the conductive elements.

However, since there is no shielding structure between the chips 11a, 11b, during high-frequency operation of the chips 11a, 11b, electromagnetic radiation can be generated, which adversely affects signals of the two chips 11a, 11b to cause electromagnetic interference to occur. As such, the operation of the semiconductor package 1 is deteriorated.

### SUMMARY OF THE INVENTION

The present invention provides an EMI (Electromagnetic Interference) shielding semiconductor element, which comprises: a substrate having a first surface and a second surface opposite to the first surface and a plurality of first conductive through holes and second conductive through holes formed in the substrate and penetrating the first and second surfaces; a redistribution layer formed on the first surface of the substrate and having a plurality of conductive pads electrically connected to the first conductive through holes; and a first metal layer formed on the redistribution layer and electrically connected to the second conductive through holes to form a shielding structure, and the first metal layer being electrically connected with the second conductive through holes, wherein a plurality of first openings are formed in the first metal layer, so as for each of the conductive pads of the redistribution layer to be positioned in a corresponding one of the first openings and to be free from being electrically connected to the first metal layer.

In an embodiment, the semiconductor element further comprises at least an electronic element disposed on and electrically connected to the conductive pads of the redistribution layer, and the electronic element is an active component, a passive component or an interposer.

In an embodiment, the second conductive through holes are arranged in a ring shape to surround the first conductive through holes.

In an embodiment, the semiconductor element further comprises a first insulating layer formed on the redistribution layer and the first metal layer and having a plurality of openings for exposing the conductive pads of the redistribution layer. The first metal layer can be partially exposed from the first insulating layer.

In an embodiment, the semiconductor element further comprises a built-up structure formed on the second surface of the substrate and having a plurality of conductive pads electrically connected to the first conductive through holes. Further, a second metal layer can be formed on the built-up structure and electrically connected to the second conductive through holes to form the shielding structure. The second metal layer has a plurality of second openings, and the conductive pads of the built-up structure are free from being electrically connected to the second metal layer. Furthermore, a second insulating layer can be formed on the built-up structure and the second metal layer and have a plurality of openings for exposing the conductive pads of the built-up structure. The second metal layer can be exposed from the second insulating layer.

The present invention further provides a semiconductor stack structure, which comprises a plurality of semiconductor elements as described above stacked on one another. The upper one of the semiconductor elements is disposed on the lower one of the semiconductor elements and the upper one of the semiconductor elements is electrically connected to the lower one of the semiconductor elements.

According to the present invention, the first metal layer and the second conductive through holes together form a shielding structure to prevent passage of electromagnetic waves into or out of the redistribution layer or side surfaces of the semiconductor element, thereby preventing electromagnetic interference from occurring between the semiconductor element and an adjacent electronic element such as a second semiconductor element.

### BRIEF DESCRIPTION OF DRAWINGS

FIG. 1 is a schematic cross-sectional view of a conventional 3D chip stack semiconductor package;

FIG. 2A is a schematic cross-sectional view of an EMI shielding semiconductor element according to a first embodiment of the present invention;

FIG. 2A′ is a schematic bottom view of the semiconductor element of FIG. 2A (the insulating layer omitted);

FIG. 2B is a schematic bottom view showing another embodiment of FIG. 2A′;

FIG. 3A is a schematic cross-sectional view of an EMI shielding semiconductor element according to a second embodiment of the present invention;

FIG. 3B is a schematic cross-sectional view of a semiconductor package formed by packaging the semiconductor element of FIG. 3A; and

FIG. 4 is a schematic cross-sectional view of a semiconductor stack structure of the present invention.

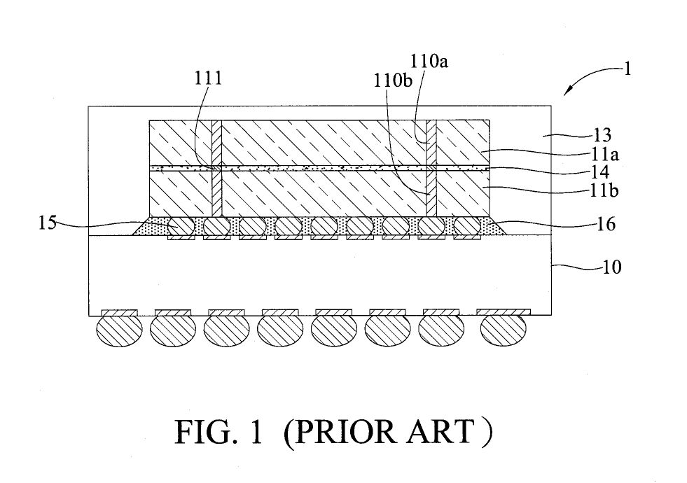

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that the drawings are only for illustrative purposes and not intended to limit the present invention. Meanwhile, terms, such as “top”, “bottom”, “upper”, “first”, “second”, “a” etc., are only used as a matter of descriptive convenience and not intended to have any other significance or provide limitations for the present invention.

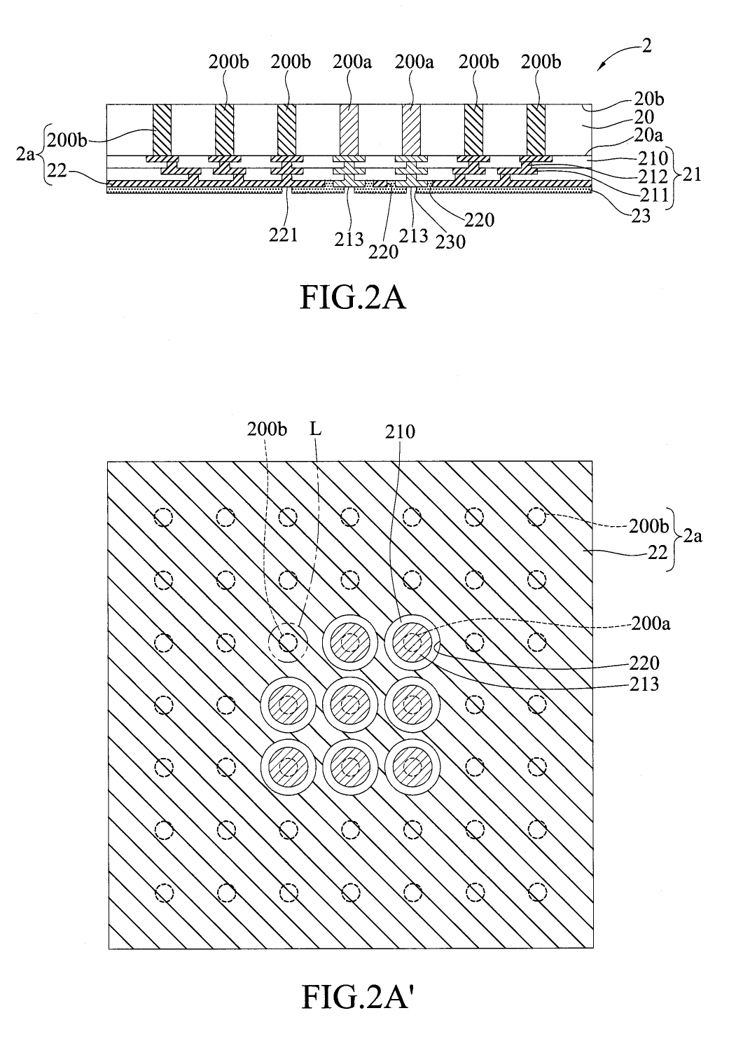

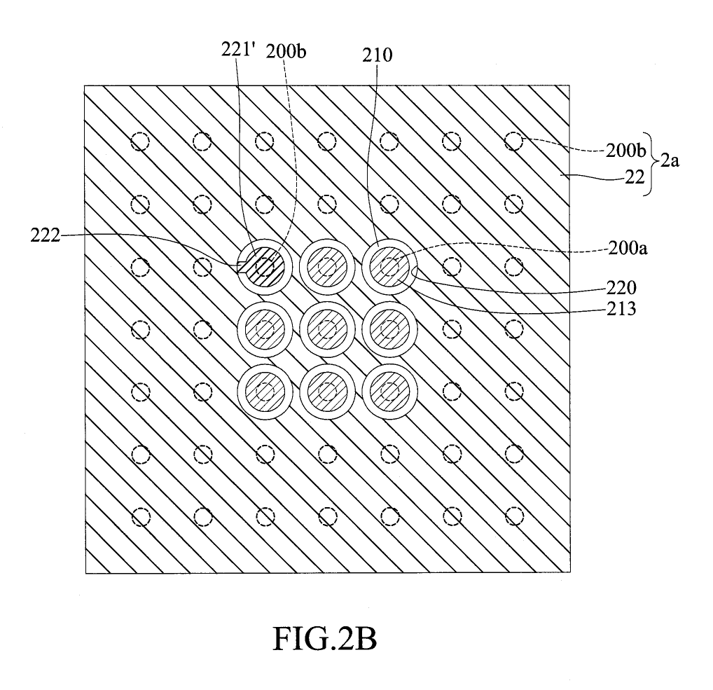

FIGS. 2A, 2A′ and 2B show an EMI shielding semiconductor element 2 according to a first embodiment of the present invention. Referring to FIG. 2A, the semiconductor element 2 has a substrate 20, a redistribution layer 21 formed on the substrate 20, a first metal layer 22 formed on the redistribution layer 21, and a first insulating layer 23 formed on the redistribution layer 21 and the first metal layer 22.

The substrate 20 is an interposer, a chip or a wafer. The substrate 20 has a first surface 20a, i.e., a bottom surface in the drawings, and a second surface 20b, i.e., a top surface in the drawings, opposite to the first surface 20a. A plurality of first conductive through holes 200a and a plurality of second conductive through holes 200b are formed in the substrate 20 to penetrate the first and second surfaces 20a, 20b.

Referring to FIG. 2A′, in an embodiment, the second conductive through holes 200b are arranged in a ring shape to surround the first conductive through holes 200a.

In an embodiment, a plurality of electronic elements (not shown) can be disposed on the second surface 20b of the substrate 20.

The redistribution layer 21 is formed on the first surface 20a of the substrate 20 through a built-up process and has a plurality of conductive pads 213 electrically connected to the first conductive through holes 200a.

In an embodiment, the redistribution layer 21 has at least a dielectric layer 210, a circuit layer 211 formed on the dielectric layer 210, and a plurality of conductive vias 212 formed in the dielectric layer 210 for electrically connecting the circuit layer 211 and the first and second conductive through holes 200a, 200b. The outermost circuit layer 211 has the conductive pads 213.

Passive components such as capacitors, inductors and resistors can be embedded in the redistribution layer 21 in various ways without any limitation.

The first metal layer 22 is formed on the outermost dielectric layer 210 of the redistribution layer 21. That is, the first metal layer 22 is located at the same layer as the conductive pads 213. Further, the first metal layer 22 is electrically connected to the second conductive through holes 200b to form a shielding structure 2a together with the second conductive through holes 200b. The first metal layer 22 has a plurality of first openings 220 for the conductive pads 213 to be exposed from the first openings 220, and the conductive pads 213 are spaced apart from the first metal layer 22, without electrically connecting the first metal layer 22, as shown in FIG. 2A′.

In an embodiment, the first metal layer 22 can be formed together with the conductive pads 213 through a patterning process.

The first insulating layer 23 is formed on the redistribution layer 21 and the first metal layer 22, and the conductive pads 213 are exposed from the first insulating layer 23. Further, a portion of the first metal layer 22 is exposed from the first insulating layer 23 to serve as grounding pads 221 for grounding an external electronic element.

In an embodiment, the first insulating layer 23 has a plurality of openings 230 for exposing the conductive pads 213 and the grounding pads 221.

Each of the grounding pads 221 can be defined by a corresponding one of the openings 230 of the first insulating layer 23, as shown in a dashed line L of FIG. 2A′. Therefore, the grounding pads 221 do not need to be formed during the fabrication of the conductive pads 213.

In another embodiment, referring to FIG. 2B, each of the grounding pads 221′ is defined by a corresponding one of the first openings 220 of the first metal layer 22. That is, the grounding pads 221′ are formed together with the conductive pads 213, and are electrically connected to the first metal layer 22 through circuits 222.

According to the present invention, the first metal layer 22 serves as a shielding structure to prevent passage of electromagnetic radiation into or out of a bottom side of the semiconductor element 2, i.e., the redistribution layer 21, thereby shielding electromagnetic interference which occurs between the semiconductor element 2 and other electronic elements.

Further, in the present invention the second conductive through holes 200b are used as a shielding structure to prevent passage of electromagnetic radiation into or out of side surfaces of the semiconductor element 2, thereby preventing electromagnetic interference from occurring between the semiconductor element 2 and other electronic elements. The first conductive through holes 200a are surrounded by the second conductive through holes 200b to achieve a preferred EMI shielding effect.

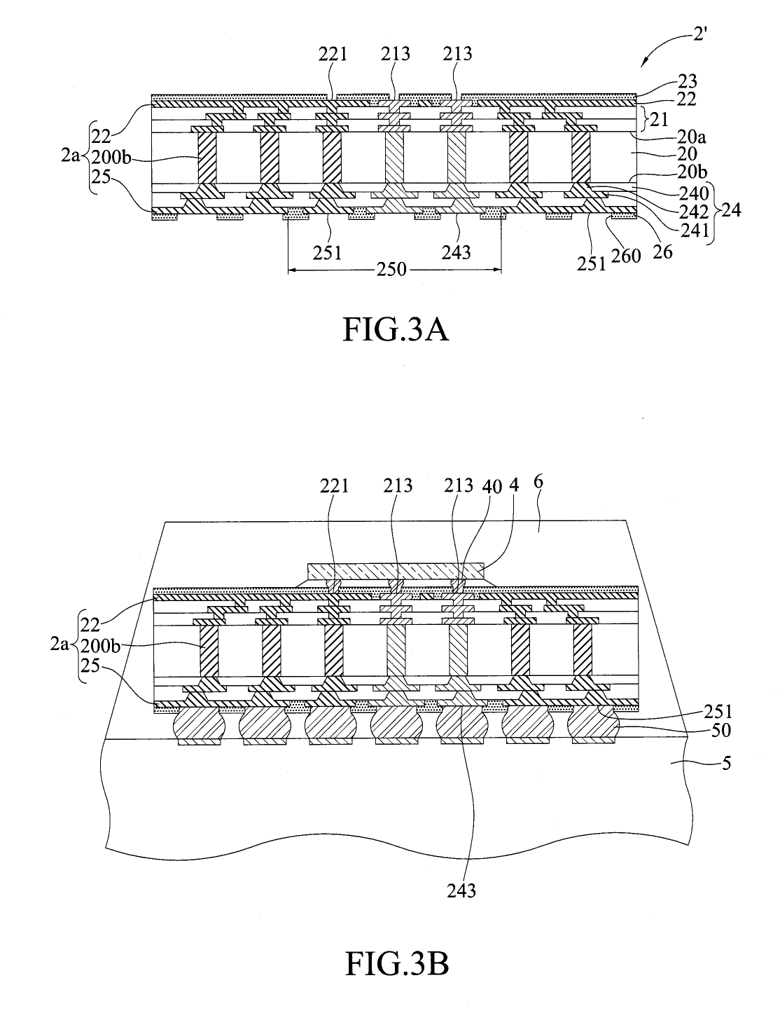

FIGS. 3A and 3B are schematic cross-sectional views showing an EMI shielding semiconductor element 2′ according to a second embodiment of the present invention. In an embodiment, the first surface 20a of the substrate 20 is a top surface, and the second surface 20b is a bottom surface.

Referring to FIG. 3A, the semiconductor element 2′ further has a built-up structure 24 formed on the second surface 20b of the substrate 20 and having a plurality of conductive pads 243 electrically connected to the first conductive through holes 200a; and a second metal layer 25 formed on the built-up structure 24.

In an embodiment, the fabrication process and structure of the built-up structure 24 of the second embodiment are substantially similar to those of the redistribution layer 21 of the first embodiment. The conductive pads 243 are formed on an outermost dielectric layer 240 of the built-up structure 24.

The second metal layer 25 is also formed on the outermost dielectric layer 240 of the built-up structure 24. That is, the second metal layer 25 is located at the same layer as the conductive pads 243. Further, the second metal layer 25 is electrically connected to the second conductive through holes 200b to form a shielding structure 2a′ together with the second conductive through holes 200b and the first metal layer 22. The second metal layer 25 has a plurality of second openings 250 for the conductive pads 243 to be exposed from the second openings 250, and the conductive pads 243 are spaced apart from the first metal layer 22, without electrically connecting the second metal layer 25.

In an embodiment, the second metal layer 25 is electrically connected to the second conductive through holes 200b through a plurality of conductive vias 242 of the built-up structure 24. The second metal layer 25 can be formed together with the conductive pads 243 through a patterning process.

The semiconductor element 2′ further has a second insulating layer 26 formed on the built-up structure 24 and the second metal layer 25 and having a plurality of openings 260 for exposing the conductive pads 243 and a portion of the second metal layer 25 serving as grounding pads 251.

Subsequently, referring to FIG. 3B, an active component such as a chip 4, a wafer, an interposer or the like is disposed on the conductive pads 213 and the grounding pads 221 through a plurality of conductive elements 40 such as solder ball. And a packaging substrate or a circuit board 5 is disposed on the conductive pads 243 and the grounding pads 251 through a plurality of conductive element 50 such as solder balls. Thereafter, an encapsulant 6 is formed to encapsulate the semiconductor element 2′ and the chip 4.

By using the first metal layer 22 as a shielding structure, the present invention prevents passage of electromagnetic radiation into or out of the redistribution layer 21 of the semiconductor element 2′, thereby preventing electromagnetic interference from occurring between the semiconductor element 2′ and the chip 4.

Further, by using the second metal layer 25 as a shielding structure, the present invention prevents passage of electromagnetic radiation into or out of the built-up structure 24 of the semiconductor element 2′, thereby shielding electromagnetic interference which occurs between the semiconductor element 2′ and the circuit board 5.

Furthermore, since the first metal layer 22 and the second metal layer 25 can be formed together with the redistribution layer 21 and the built-up structure 24, the present invention eliminates the need to form a shielding layer on the encapsulant 6 after the packaging process, thereby simplifying the fabrication process, reducing the fabrication cost and preventing signals of the electronic elements of the package from affecting each other.

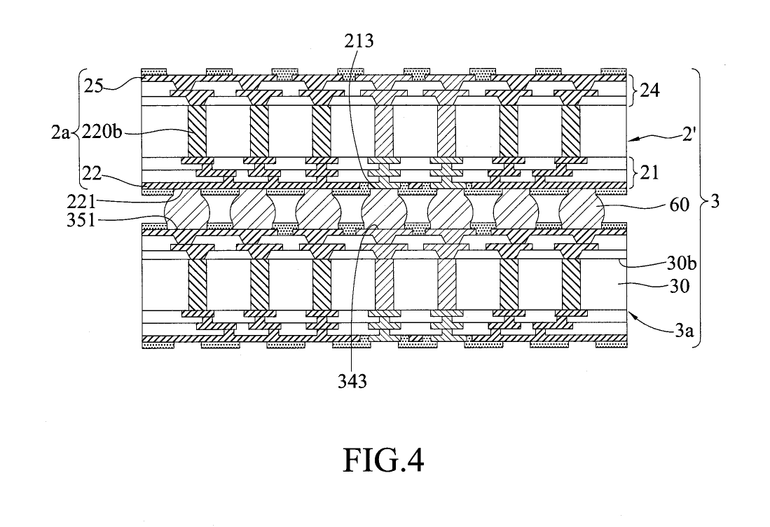

FIG. 4 is a cross-sectional view showing a semiconductor stack structure 3 according to the present invention. The semiconductor stack structure 3 has two semiconductor elements as described in the second embodiment.

In the semiconductor stack structure 3, an upper semiconductor element 2′ is disposed on a lower semiconductor element 3a in a manner that the second surface 30b of the substrate 30 of the lower semiconductor element 3a is attached to the first surface 20a of the substrate 20 of the upper semiconductor element 2′. In particular, a plurality of conductive elements 60 such as solder balls are formed to connect the conductive pads 343 and the grounding pads 351 of the lower semiconductor element 3a to the conductive pads 213 and the grounding pads 221 of the upper semiconductor element 2′, respectively.

Further, an active component such as a chip can be disposed on the built-up structure 24. In another embodiment, the second surface 30b of the substrate 30 of the lower semiconductor element 3a has a plurality of active components disposed thereon.

In the semiconductor stack structure 3, the first metal layer 22 is used as a shielding structure to prevent passage of electromagnetic radiation into or out of the redistribution layer 21 of the semiconductor element 2′, thereby preventing electromagnetic interference from occurring between the semiconductor element 2′ and the lower semiconductor element 3a.

It should be noted that a plurality of semiconductor elements 2 as in the first embodiment or in the second embodiment can be stacked on one another in the above-described manner.

Therefore, the first metal layer and the second metal layer can shield electromagnetic interference which occurs in a vertical direction and the second conductive through holes can shield electromagnetic interference which occurs in a horizontal direction, thereby effectively preventing interference of signals from various electronic elements in a semiconductor package.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A semiconductor element, comprising:
a substrate having a first surface and a second surface opposite to the first surface and a plurality of first conductive through holes and second conductive through holes formed in the substrate and penetrating the first and second surfaces;
a redistribution layer formed on the first surface of the substrate and having a plurality of conductive pads electrically connected to the first conductive through holes; and
a first metal layer formed on the redistribution layer and electrically connected to the second conductive through holes to form a shielding structure, wherein a plurality of first openings are formed in the first metal layer, so as for each of the conductive pads of the redistribution layer to be positioned in a corresponding one of the first openings and to be free from being electrically connected to the first metal layer.

2. The semiconductor element of claim 1, further comprising at least an electronic element disposed on and electrically connected to the conductive pads of the redistribution layer.

3. The semiconductor element of claim 2, wherein the electronic element is an active component, a passive component or an interposer.

4. The semiconductor element of claim 1, wherein the second conductive through holes are arranged in a ring shape to surround the first conductive through holes.

5. The semiconductor element of claim 1, further comprising a first insulating layer formed on the redistribution layer and the first metal layer and having a plurality of openings for exposing the conductive pads of the redistribution layer.

6. The semiconductor element of claim 5, wherein the first metal layer is partially exposed from the first insulating layer.

7. The semiconductor element of claim 1, further comprising a built-up structure formed on the second surface of the substrate and having a plurality of conductive pads electrically connected to the first conductive through holes.

8. The semiconductor element of claim 7, further comprising a second metal layer formed on the built-up structure and electrically connected to the second conductive through holes to form the shielding structure, wherein a plurality of second openings are formed in the second metal layer, and the conductive pads of the built-up structure are free from being electrically connected to the second metal layer.

9. The semiconductor element of claim 8, further comprising a second insulating layer formed on the built-up structure and the second metal layer and having a plurality of openings for exposing the conductive pads of the built-up structure.

10. The semiconductor element of claim 9, wherein the second metal layer is partially exposed from the second insulating layer.

11. A semiconductor stack structure, comprising: a plurality of semiconductor elements according to claim 1 stacked on one another, wherein an upper one of the semiconductor elements is disposed on a lower one of the semiconductor elements and the upper one of the semiconductor elements is electrically connected to the lower one of the semiconductor elements.

12. The semiconductor stack structure of claim 11, further comprising at least an electronic element disposed on and electrically connected to the upper one of the semiconductor elements.

13. The semiconductor stack structure of claim 12, wherein the electronic element is an active component or a passive component

14. The semiconductor stack structure of claim 11, wherein the second conductive through holes are arranged in a ring shape to surround the first conductive through holes.

15. The semiconductor stack structure of claim 11, further comprising a first insulating layer formed on the redistribution layer and the first metal layer and having a plurality of openings for exposing the conductive pads of the redistribution layer.

16. The semiconductor stack structure of claim 15, wherein the first metal layer is partially exposed from the first insulating layer.

17. The semiconductor stack structure of claim 11, further comprising a built-up structure formed on the second surface of the substrate and having a plurality of conductive pads electrically connected to the first conductive through holes.

18. The semiconductor stack structure of claim 17, further comprising a second metal layer formed on the built-up structure and electrically connected to the second conductive through holes to form the shielding structure, wherein a plurality of second openings are formed in the second metal layer, and the conductive pads of the built-up structure are free from being electrically connected to the second metal layer.

19. The semiconductor stack structure of claim 18, further comprising a second insulating layer formed on the built-up structure and the second metal layer and having a plurality of openings for exposing the conductive pads of the built-up structure.

20. The semiconductor stack structure of claim 19, wherein the second metal layer is exposed from the second insulating layer.
